(19) United States
(12) Patent Application Publication
(10) Pub. No.: US 2009/0021915 A1
(43) Pub. Date: Jan. 22, 2009

(54) Multi-layer heat-dissipating device

(75) Inventor: Ting-Chang Kuo, Taipei (TW)

Correspondence Address: BACON & THOMAS, PLLC, 625 SLATERS LANE, FOURTH FLOOR, ALEXANDRIA, VA, 22314-1176, US

(73) Assignee: Inventec Multimedia & Telecom (Tianjin) Co., Ltd., Tianjin (CN)

(21) Appl. No.: 11/826,603

(22) Filed: Jul. 17, 2007

(51) Int. Cl. H05K 7/20

(52) U.S. Cl. 361/704; 361/707; 165/185

(57) ABSTRACT

A multi-layer heat-dissipating device is provided. The multi-layer heat-dissipating device does not use fans, absorbs heat energy sequentially with heat-conducting elements and a heat-dissipating metal sheet, and effectively blocks heat radiation of a heat-generating element, so as to achieve the effects of power saving, no noise, and less occupied space.

### BACKGROUND OF THE INVENTION

1. Field of Invention

The present invention relates to a heat-dissipating device of a heat-generating element, and more particularly to a multi-layer heat-dissipating device using heat-conducting elements and a heat-dissipating metal sheet to absorb heat sequentially.

2. Related Art

In recent years, with the development of the semiconductor industry along with advanced semiconductor processes, semiconductor chips are becoming smaller and smaller, and the processing speeds thereof are significantly increased. However, the heat generated by the chips is quite high accordingly. Therefore, in the trend that the electronic products are smaller but have high speeds, it has become an unignorable issue to solve the heat dissipation problem of the semiconductor chips.

According to conventional heat dissipation methods for semiconductor chips, a heat-dissipating sheet is tightly attached above a surface contacting the air of a semiconductor chip to improve the area of the semiconductor contacting the air, so as to realize the heat dissipation. However, as the temperature of the semiconductor chips is rising significantly with the increase of the processing speeds of the semiconductor chips, conventional heat-dissipating sheets are insufficient in practice.

Therefore, in order to improve the heat dissipation performance of the heat-dissipating sheets, a general heat dissipation method currently is air cooling heat dissipation. As shown in FIG. 1, a metal heat-dissipating sheet 13 of a high thermal conductivity coefficient and having a plurality of fins is tightly attached on a surface of a heat-generating element 12 on a printed circuit board 11, so as to improve the area of the heat-generating element 12 contacting the air. Moreover, a fan 14 is used, which rotates to draw out airflow or blow the airflow to the metal heat-dissipating sheet 13 of the high heat conductivity coefficient, so as to bring out the heat generated by the heat-generating element 12. Thus, the heat dissipation is realized. However, this heat dissipation method will cause the problems such as noise, power consumption, and occupied space.

Modem electronic devices are developed to be smaller, multi-functional, and power saving, the conventional air cooling heat dissipation still requires an additional power to drive the fan, and must be improved in terms of volume.

### SUMMARY OF THE INVENTION

The present invention is directed to providing a multi-layer heat-dissipating device, which does not use fans, absorbs heat in different stages according to a sequential concept, and effectively blocks heat radiation of the heat-generating element. Thus, the heat is effectively absorbed and discharged without using the fans.

In order to solve the aforementioned problem, the present invention provides a multi-layer heat-dissipating device disposed in an electronic device having a plastic case. The multi-layer heat-dissipating device includes a heat-dissipating fin set, a first heat-conducting element, a heat-dissipating metal sheet, and a second heat-conducting element. The heat-dissipating fin set contacts the heat-generating element that generates heat. The first heat-conducting element is attached on a top end of the heat-dissipating fin set, for conducting the heat of the heat-dissipating fin set. The heat-dissipating metal sheet is attached on the first heat-conducting element, for absorbing the heat conducted by the heat-conducting element, and blocking the heat radiation of the heat-generating element.

The present invention provides a multi-layer heat-dissipating device that uses heat-conducting elements and a heat-dissipating metal sheet to form a plurality of heat dissipation layers for absorbing heat sequentially, and uses the heat-dissipating metal sheet to replace fans. The heat-conducting elements improve the heat conductivity between different heat dissipation layers, so as to achieve the effects of power saving, no noise, and less occupied space. When the area of the heat-dissipating metal sheet is larger, the heat dissipation effect is better, and the effect of blocking the heat radiation is also better.

In order to make the aforementioned and other objects, features and advantages of the present invention comprehensible, a preferred embodiment accompanied with figures is described in detail below.

### BRIEF DESCRIPTION OF THE DRAWINGS

FIG. 1 is a schematic view of a conventional air cooling heat dissipation method.

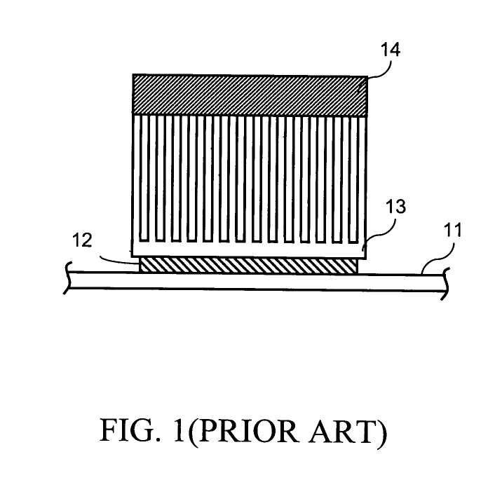

FIG. 2 is a schematic view of a multi-layer heat-dissipating device according to the present invention.

FIG. 3 is a schematic stereogram of the multi-layer heat-dissipating device according to the present invention.

### DETAILED DESCRIPTION OF THE INVENTION

The present invention provides a multi-layer heat-dissipating device, which does not use fans, absorbs heat in different stages according to a sequential concept, and effectively blocks heat radiation of the heat-generating element. Thus, the heat is effectively absorbed and discharged without using the fans.

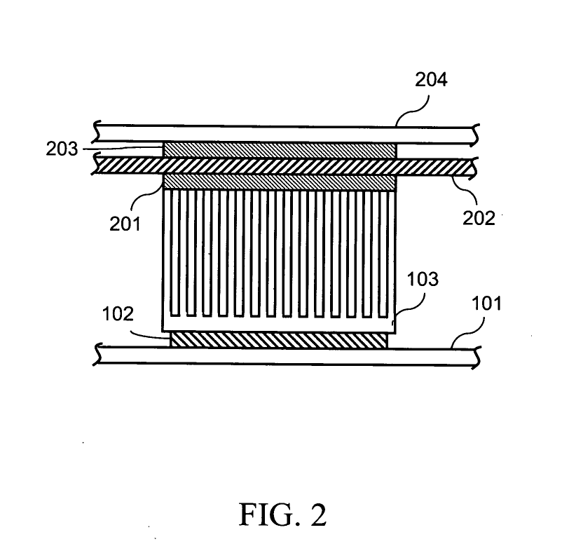

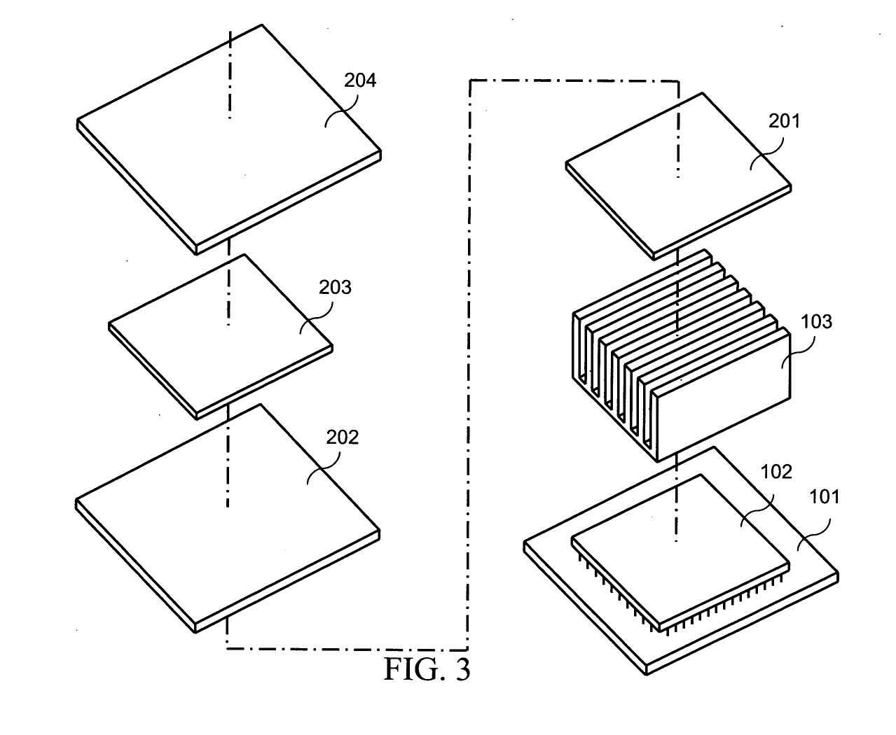

FIGS. 2 and 3 are schematic views of a multi-layer heat-dissipating device according to the present invention, which includes a printed circuit board 101, a heat-generating element 102, a heat-dissipating fin set 103, a first heat-conducting element 201, a heat-dissipating metal sheet 202, a second heat-conducting element 203, and a plastic case 204. The printed circuit board 101 is a circuit substrate for disposing electronic elements. The heat-generating element 102 is a semiconductor chip, such as a CPU, Southbridge and Northbridge chip sets, or a system-on-chip. The heat-dissipating fin set 103 is made of a material with fine thermal conductivity, e.g., a material selected from a group consisting of Cu, Al, Mg, Fe, Sn, Pb, Zn, Au and Ag. A heat-conducting adhesive is coated on a contact surface between the heat-dissipating fin set 103 and the heat-generating element 102, so as to contact the heat-generating element 102 that generates heat. The first heat-conducting element 201 is a heat-conducting silicon rubber with adhesives on both sides, and is attached to a top end of the heat-dissipating fin set, so as to conduct the heat of the heat-dissipating fin set 103. The heat-dissipating metal sheet 202 is a thin metal sheet mostly made of aluminum, has an area maximized in a most appropriate manner, and is attached on the first heat-conducting element 201, so as to absorb the heat conducted by the first heat-conducting element 201, and block the heat radiation of the heat-generating element 102. The material of the second heat-conducting element 203 is the same as that of the first heat-conducting element 201, while the difference lies in that the second heat-conducting element 203 is attached on the heat-dissipating metal sheet 202, so as to conduct the heat of the heat-dissipating metal sheet 202 to the plastic case 204. The plastic case 204 is the outermost component of an electronic product, and presses various composition layers, such that the composition layers are attached tightly, so as to protect the electronic product and to dissipate heat.

The entire heat conduction flow of the multi-layer heat-dissipating device is as follows. The heat-dissipating fin set 103 tightly attached on the heat-generating element 102 performs the heat absorption of the first stage. As the thermal conductivity of the heat-dissipating fin set 103 is fine, and has a larger area contacting the air than the heat-generating element 102, the heat dissipation efficiency of the heat-generating element 102 is improved. Then, the first heat-conducting element 201 conducts the heat of the heat-dissipating fin set 103 to the heat-dissipating metal sheet 202, such that the heat-dissipating metal sheet 202 performs the heat absorption of the second stage. Finally, the second heat-conducting element 203 conducts the heat of the heat-dissipating metal sheet 202 to the plastic case 204, such that the plastic case 204 performs the heat absorption of the third stage. Till now, the entire heat conduction flow of the heat-generating element 102 is completed. Thus, the multi-layer heat-dissipating device of the present invention does not use fans, absorbs heat sequentially with the heat-conducting elements and the heat-dissipating metal sheet 202, and effectively blocks heat radiation of the heat-generating element 102, so as to achieve the effects of power saving, no noise, and less occupied space.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A multi-layer heat-dissipating device, disposed in an electronic product having a plastic case, for effectively dissipating heat generated by a heat-generating element on a printed circuit board of the electronic product, comprising:
a heat-dissipating fin set, having a bottom end contacting the heat-generating element for dissipating heat;
a first heat-conducting element, attached on a top end of the heat-dissipating fin set, for conducting heat of the heat-dissipating fin set; and
a heat-dissipating metal sheet, attached on the first heat-conducting element, for absorbing heat conducted by the first heat-conducting element.

2. The multi-layer heat-dissipating device as claimed in claim 1, further comprising:
a second heat-conducting element, attached between the heat-dissipating metal sheet and the plastic case, for conducting heat of the heat-dissipating metal sheet to the plastic case.

3. The multi-layer heat-dissipating device as claimed in claim 1, wherein a heat-conducting adhesive is further coated on a contact surface between the heat-dissipating fin set and the heat-generating element.

4. The multi-layer heat-dissipating device as claimed in claim 1, wherein the heat-dissipating fin set and the heat-dissipating metal sheet are made of one selected from a group consisting of Cu, Al, Mg, Fe, Sn, Pb, Zn, Au and Ag.

5. The multi-layer heat-dissipating device as claimed in claim 1, wherein the heat-generating element is a semiconductor chip.

6. The multi-layer heat-dissipating device as claimed in claim 1, wherein the heat-dissipating metal sheet is fabricated to an appropriate size and shape, or has a same length as the plastic case, for blocking heat radiation of the heat-generating element.

7. The multi-layer heat-dissipating device as claimed in claim 2, wherein the first heat-conducting element and the second heat-conducting element are heat-conducting silicon rubber with adhesives on both sides.
